(19) United States
(12) Patent Application Publication
(10) Pub. No.: US 2025/0052691 A1
(43) Pub. Date: Feb. 13, 2025

(54) SEMICONDUCTOR MEASUREMENT APPARATUS AND METHOD OF MANUFACTURING SEMICONDUCTOR DEVICE USING SEMICONDUCTOR MEASUREMENT APPARATUS

(71) Applicant: Samsung Electronics Co., Ltd., Suwon-si (KR)

(72) Inventors: Youngsun CHOI, Suwon-si (KR); Soonyang KWON, Suwon-si (KR); Kwangrak KIM, Suwon-si (KR); Jangryul PARK, Suwon-si (KR); Jiwoong KIM, Suwon-si (KR); Youngjun LEE, Suwon-si (KR)

(73) Assignee: Samsung Electronics Co., Ltd., Suwon-si (KR)

(21) Appl. No.: 18/394,784

(22) Filed: Dec. 22, 2023

(30) Foreign Application Priority Data
Aug. 11, 2023 (KR) 10-2023-0105272

(51) Int. Cl. G01N 21/956; G01J 3/02; G01J 3/06; G01J 3/45; H01L 21/66

(52) U.S. Cl. CPC G01N 21/95607; G01J 3/0254; G01J 3/0275; G01J 3/0278; G01J 3/06; G01J 3/45; H01L 22/20; G01J 2003/064; G01N 2021/95615; G01N 2201/105; G01N 2201/11

(57) ABSTRACT

A method of manufacturing a semiconductor device using a semiconductor measurement apparatus includes extracting an interference pattern using a microsphere, and measuring a distance between a specimen and the microsphere, based on the interference pattern. A semiconductor measurement apparatus includes a light source configured to output at least one light, a scanner having a microsphere-objective lens, the scanner configured to allow the at least one light to be incident on a specimen, a spectrometer configured to obtain a spectrum of light reflected from the specimen; and a distance measurement apparatus configured to calculate a microsphere-to-specimen distance by analyzing a change in the spectrum.

### CROSS-REFERENCE TO RELATED APPLICATION(S)

This application claims benefit of priority to Korean Patent Application No. 10-2023-0105272 filed on Aug. 11, 2023 in the Korean Intellectual Property Office, the contents of which is incorporated herein by reference in its entirety.

### BACKGROUND

Various example embodiments relate to a semiconductor measurement apparatus and/or a method of manufacturing a semiconductor device using the same.

In general, non-destructive three-dimensional (3D) spectroscopic measurement for process control is becoming increasingly important as semiconductor processes become ultra-sophisticated and/or yield critical. Alternatively or additionally, as semiconductor products have an ultra-small size, a size of a measurement target region (spot size) required for testing and measurement is gradually becoming smaller. During spectroscopic measurement, the measurement target region is determined by the performance of a light source, condensing lens, camera, or the like. The performance of components for non-destructive testing is becoming increasingly sophisticated and may already reach physical and/or optical limits (Rayleigh limits) thereof. As a result, research has been undertaken to dramatically reduce the measurement target region during spectroscopic measurement.

### SUMMARY

Various example embodiments may provide a semiconductor measurement apparatus for improving one or more of the stability, precision, and speed of a microsphere optical system, and/or a method of manufacturing a semiconductor device using the same.

According to some example embodiments, there is provided a method of manufacturing a semiconductor device using a semiconductor measurement apparatus, the method including extracting an interference pattern using a microsphere, and measuring a distance between a specimen and the microsphere, the measuring based on the interference pattern.

Alternatively or additionally according to various example embodiments, there is provided a method of manufacturing a semiconductor device using a semiconductor measurement apparatus, the method including performing a spot scanning operation on a specimen while moving a scanner having a microsphere-objective lens, measuring a microsphere to specimen distance based on an interference pattern generated in the spot scanning operation, and compensating for an error of the scanner in the microsphere-to-specimen distance.

Alternatively or additionally according to various example embodiments, there is provided a method of manufacturing a semiconductor device using a semiconductor measurement apparatus, the method including extracting an interference pattern for light reflected from a specimen by using a microsphere, and determining at least one of a distance to the specimen, a height of the specimen, or a thickness of the specimen, based on a spectrum through the microsphere-objective lens corresponding to the interference pattern.

Alternatively or additionally according to various example embodiments, there is provided a semiconductor measurement apparatus including a light source configured to output at least one light, a scanner having a microsphere-objective lens, the scanner configured to allow the at least one light to be incident on a specimen, a spectrometer configured to obtain a spectrum of light reflected from the specimen, and a distance measurement apparatus configured to calculate a microsphere-specimen distance by analyzing a change in the spectrum.

Alternatively or additionally according to various example embodiments, there is provided a computing device including at least one processor, and a memory device configured to store a measurement tool executable on the at least one processor. The measurement tool may be configured to extract an interference pattern corresponding to a spectral change in light reflected from a specimen by using a microsphere, and may be configured to determine at least one of a microsphere to specimen distance, a height of the specimen, or a thickness of the specimen, based on the interference pattern.

### BRIEF DESCRIPTION OF DRAWINGS

The above and other aspects, features, and advantages of various example embodiments will be more clearly understood from the following detailed description, taken in conjunction with the accompanying drawings, in which:

FIGS. 1A and 1B are example diagrams illustrating a narrow region outside of a cell of a general memory device;

FIGS. 2A and 2B are example diagrams illustrating a light-gathering effect using a microsphere and a super-resolution effect of an optical system using the same;

FIG. 3 is an example diagram illustrating specifications and/or features of a microsphere-objective lens according to various example embodiments;

FIGS. 4A and 4B are diagrams illustrating a reflection spectrum obtained from a SiO₂ step wafer using a semiconductor measurement apparatus and an intensity according to a position of an objective lens according to various example embodiments;

FIG. 5A is an example diagram illustrating a semiconductor measurement apparatus according to the related art using a general position measurement sensor, and FIG. 5B is an example diagram illustrating a semiconductor measurement apparatus according to the present inventive concept;

FIG. 6A is an example diagram illustrating a semiconductor measurement apparatus 10 according to various example embodiments, and FIGS. 6B, 6C, and 6D are example diagrams illustrating a method of measuring, by a semiconductor measurement apparatus 10, a distance according to various example embodiments;

FIGS. 7A, 7B, and 7C are example diagrams illustrating an operating principle of a semiconductor measurement apparatus 10 according to various example embodiments;

FIG. 8 is an example diagram illustrating a real-time distance measurement process of a semiconductor measurement apparatus 10 according to various example embodiments;

FIG. 9 is an example diagram illustrating a two-dimensional (2D) region scanning of a semiconductor measurement apparatus 10 according to various example embodiments;

FIG. 10 is an example diagram illustrating a 2D spectrum map of a semiconductor measurement apparatus 10 according to various example embodiments;

FIG. 11A is an example diagram illustrating a height standard specimen according to various example embodiments, and FIG. 11B is an example diagram illustrating a standard specimen measurement result according to various example embodiments;

FIG. 12 is an example flowchart illustrating an operation of a semiconductor measurement apparatus according to various example embodiments;

FIG. 13 is an example flowchart illustrating an operation of manufacturing a semiconductor device using a semiconductor measurement apparatus according to various example embodiments;

FIGS. 14A, 14B, and 14C are example diagrams illustrating obtaining of a reference pattern according to various example embodiments;

FIG. 15 is an example flowchart illustrating an operation of a semiconductor measurement apparatus according to various example embodiments;

FIGS. 16A, 16B, and 16C are example diagrams illustrating measuring, by a semiconductor measurement apparatus, a surface shape of a specimen according to various example embodiments;

FIG. 17 is a flowchart illustrating an operation of a measurement apparatus according to various example embodiments; and

FIG. 18 is a block diagram illustrating a computing device 1000 performing a semiconductor measurement operation according to various example embodiments.

### DETAILED DESCRIPTION

Hereinafter, some example embodiments concept will be described clearly and specifically, such that a person skilled in the art easily could carry out and/or practice example embodiments using the drawings.

A semiconductor measurement apparatus and/or a method of manufacturing a semiconductor device using the same according to various example embodiments may measure a working distance for a super-resolution microsphere optical system. Here, the microsphere optical system may include an objective lens to which a microsphere is attached, a spectrometer, a broadband light source, and the like. Details of the microsphere optical system will be described in US 2022-0049949 and US 2023-0028347, which were applied for by Samsung Electronics Co Ltd and are herein incorporated by reference in their entirety. The microsphere optical system may have nanometer (nm)-level precision and may use an interference phenomenon occurring in the microsphere optical system itself to enable measurement of a height of a microstructure having a spot size of 100 nm. Alternatively or additionally, the microsphere optical system may be installed coaxially with the objective lens. The semiconductor measurement apparatus and/or the method of manufacturing a semiconductor device using the same according to various example embodiments may enable measurement of a height of a microstructure with a small spot size, may not require an additional configuration of the optical system, may enable direct measurement of a working distance of the objective lens, and may perform super-precise position control corresponding to super-resolution (SR) equipment using a microsphere.

A general spectroscopic measurement apparatus may have a spot size of at least 5 μm and a spatial resolution of 2 μm due to a diffraction limit, using a method of obtaining a spectroscopic measurement through a microscope optical system. A measurement region required for testing and measurement of recently ultra-minimized semiconductor products ranges from tens of nm to several μm, making measurement impossible with the general spectroscopic measurement apparatus.

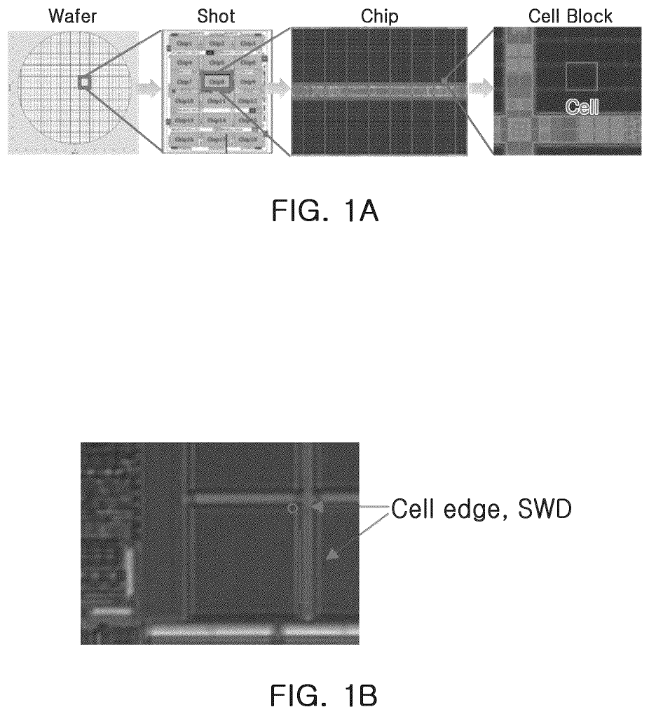

FIGS. 1A and 1B are example diagrams illustrating a narrow region outside of a cell of a general memory device. As illustrated in FIG. 1A, in a semiconductor device such as a memory device, a cell block may have a size of several tens of microns (μm). As illustrated in FIG. 1B, the narrow region outside of the cell may have a size of 2 μm. In this case, it may be difficult to measure an outermost portion of the cell and the narrow region outside of the cell in which a locality issue occurs when applying the general spectroscopic measurement apparatus.

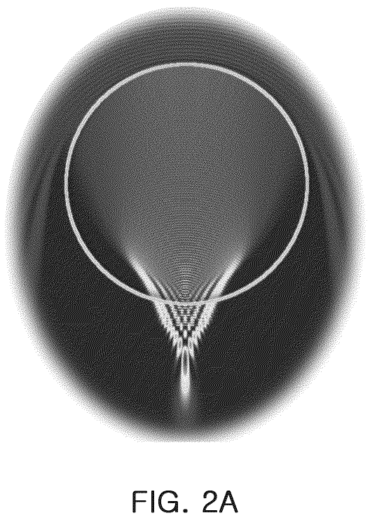

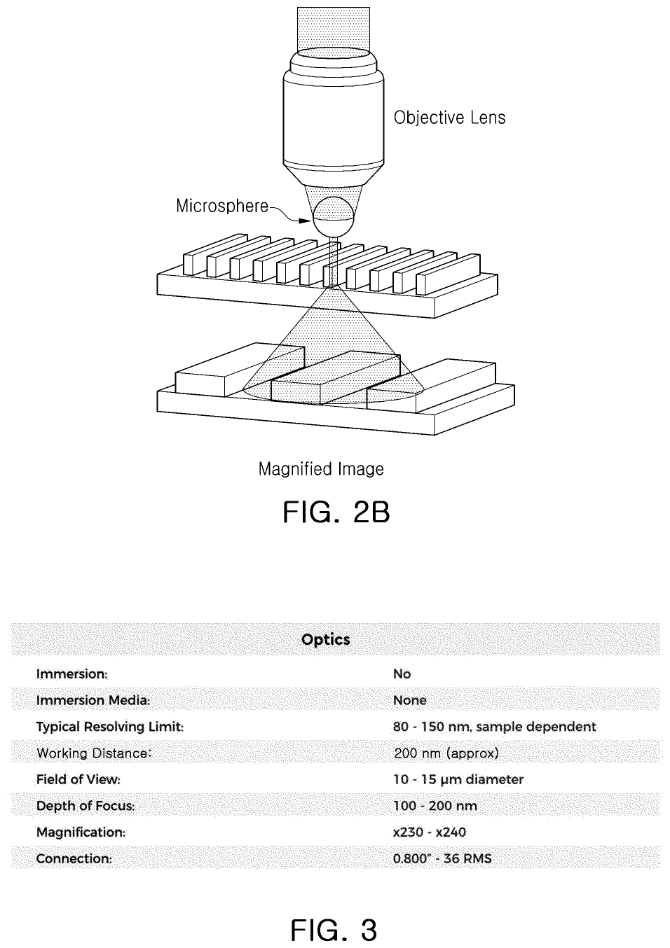

FIGS. 2A and 2B are example diagrams illustrating a light-gathering effect using a microsphere and a super-resolution effect of an optical system using the same. Referring to FIG. 2A, a measurement method using a microsphere, which is or corresponds to one of technologies introduced to overcome or improve upon an optical diffraction limit, may use a light-gathering effect known as a photonic nanojet generated in a sphere having a size (or a diameter) of several μm. In general, the photonic nanojet light-gathering effect may be an innovative phenomenon in which optics and nanotechnology are combined with each other. The photonic nanojet light-gathering effect may refer to a phenomenon in which light is concentrated around a specific nanostructure when the nanostructure is irradiated with light. When light is irradiated at a specific frequency, such as a resonance frequency, using a nanostructure or nanostructure pattern formed of a specific material, such a light-gathering effect focuses energy of light which corresponds to the resonance frequency, onto the nanostructure. As a result, optical intensity much greater than those of surroundings may be achieved. As described above, a photonic nanojet may achieve additional magnification of up to several tens of times, which may dramatically improve spatial resolution, and/or may reduce spot size.

A general optical system may place an objective lens in an appropriate position using various focus control (such as autofocus) methods. Conversely, in a spectroscopic optical system using a microsphere, a general focus control method may not work due to various effects such as one or more of a noticeably short working distance, chromatic aberration, and a multiple reflection phenomenon. Accordingly, such a microsphere spectroscopic optical system may require or may use spectrum acquisition in a focal position, such as a dynamically determined (or, alternatively, predetermined) focal position through accurate focus control because a spectrum for each wavelength, which is a structural measurement signal, is sensitive to changes in a position of the objective lens.

As illustrated in FIG. 2B, a microsphere optical system may reduce a spot size and/or improve resolution beyond a diffraction limit. However, there may be difficulties in focus control due to a difference from a general optical system, such as one or more of working distance, chromatic aberration, multiple reflection, or the like. The semiconductor measurement apparatus according to various example embodiments includes an ultra-precise focus control technology using distance measurement. The ultra-precise focus control technology may overcome or at least partly overcome difficulties, such as a short working distance of 100 nm and/or a spectral sensitivity requiring or expecting a precision of 10 nm or less, and/or may also be applied to measurement of a height and thickness of a specimen.

FIG. 3 is an example diagram illustrating specifications or expectations of a microsphere-objective lens according to various example embodiments. Referring to FIG. 3, a working distance of 200 nm may be very short, as compared to a general optical system. The microsphere spectroscopic optical system may have a risk of collision between a microsphere and a specimen due to the noticeably short working distance. As a result, a measurement apparatus using the microsphere spectroscopic optical system may cause a decrease in measurement speed.

For example, a focal point, formed by a photonic nanojet effect, may be generally positioned at a point close to a microsphere, e.g., only a few microns away. A surface of a specimen may need to be or may be expected to be positioned between a photonic nanojet and the microsphere, such that the specimen may be actually positioned to be very close to the microsphere. The microsphere-objective lens may have a working distance of 200 nm, such that an approaching speed may be expected to be extremely reduced for safety reasons, which may lead to a decrease in measurement throughput. Accordingly, a distance between the specimen and the microsphere may need to be or may be expected to be accurately or more accurately measured. When such precise distance measurement is possible, time required to place the microsphere on the specimen surface may be dramatically reduced. Alternatively or additionally, in the microsphere spectroscopic optical system unlike the general optical system, a working distance and a depth of focus may be similar to each other. Accordingly, it may be difficult to perform repeatable control using a focus alignment method according to the related art, and accurately measuring the working distance may be necessary or desirable.

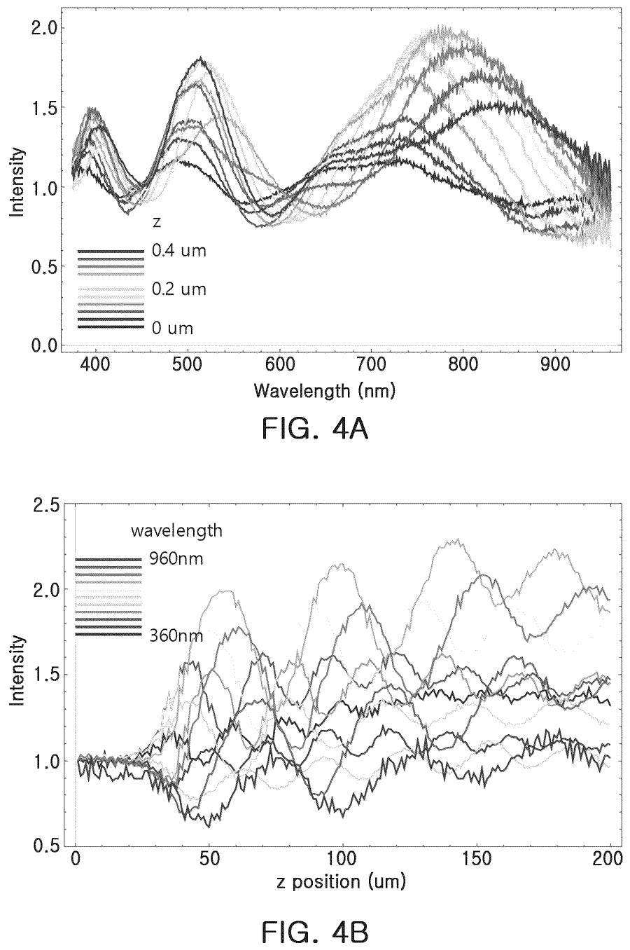

FIGS. 4A and 4B are diagrams illustrating a reflection spectrum obtained from a wafer with a step, e.g., an oxide SiO₂) step, using a semiconductor measurement apparatus and an intensity according to a position of an objective lens, according to various example embodiments. Spectral sensitivity according to a measurement distance may require or may use a distance precision of 10 nm or less. When a microsphere-objective lens is used, a spectrum may have greatly increased sensitivity due to multiple reflection between a specimen and a microsphere. In order to obtain a spectral repeatability of 2%, position control having a precision of 10 nm or less may be required.

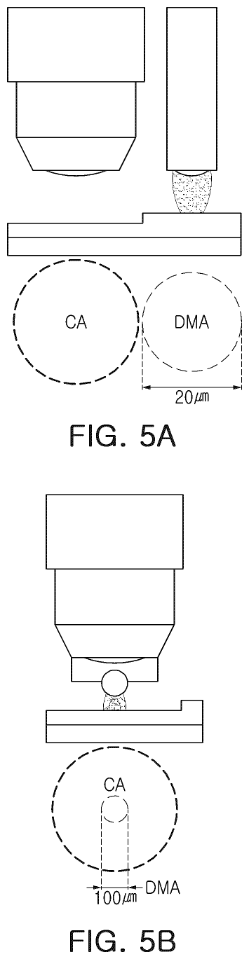

FIG. 5A is an example diagram illustrating a semiconductor measurement apparatus according to related art using a general position measurement sensor, and FIG. 5B is an example diagram illustrating a semiconductor measurement apparatus according to various example embodiments. Referring to FIG. 5A, a new laser interferometer may be required or used, in addition to an optical system according to the related art, so as to measure a distance between an objective lens and a specimen. However, the laser interferometer may not be installed coaxially or collinearly with an objective lens-specimen. As a result, the semiconductor measurement apparatus according to the related art may not accurately measure a distance between the specimen and a microsphere. Alternatively or additionally, a general distance measurement sensor may have a spot size several tens of times larger than that of a microsphere optical system, and thus may not measure a height of a microstructure. Conversely, the semiconductor measurement apparatus according to various example embodiments may include a microsphere optical system installed coaxially or collinearly with an objective lens-specimen, and thus may measure a height of a microstructure using a photonic nanojet focusing effect with respect to a microsphere, as illustrated in FIG. 5B.

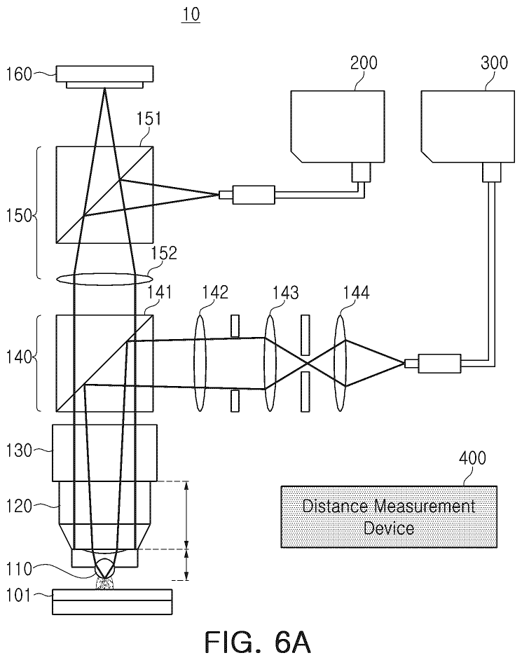

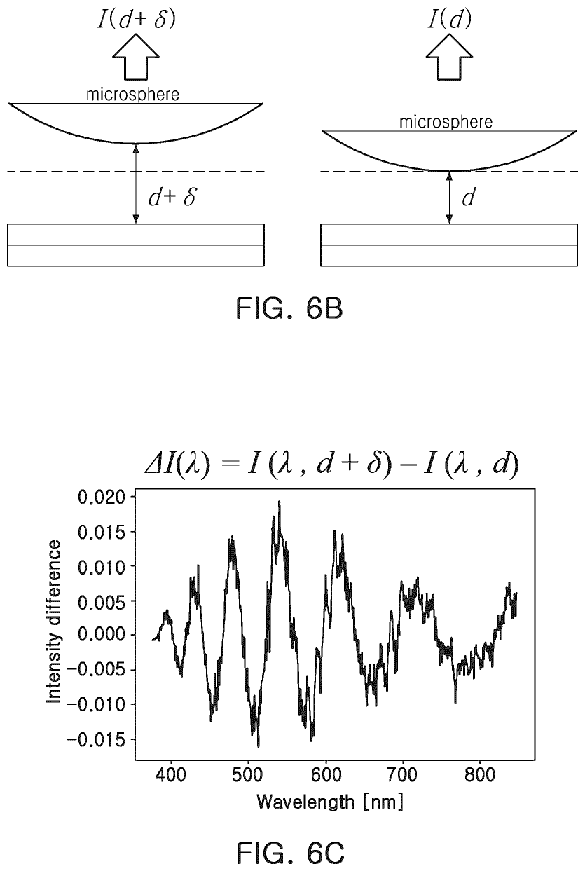

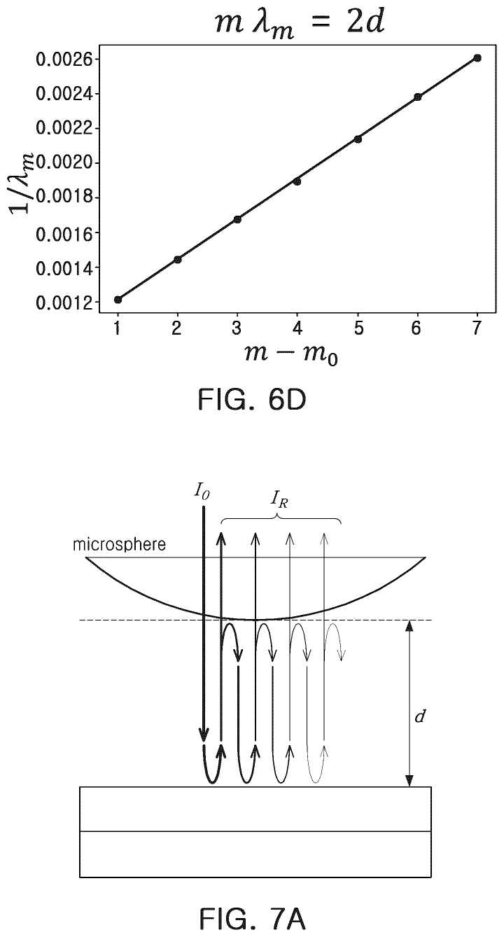

FIG. 6A is an example diagram illustrating a semiconductor measurement apparatus 10 according to various example embodiments. Referring to FIG. 6A, the semiconductor measurement apparatus 10 may include a microsphere 110, an objective lens 120, an objective lens position controller 130, a first optical system 140, a second optical system 150, a camera 160, a spectrometer 200, a light source 300, and a distance measurement apparatus 400. Here, the microsphere 110, the objective lens 120, the objective lens position controller 130, the first optical system 140, second optical system 150, the and camera 160 may be collectively referred to as a scanner.

A substrate 101 may be loaded on a stage. Here, the stage may be disposed within the semiconductor measurement apparatus 10. A semiconductor pattern, such as a grating pattern, may be formed on an upper surface of the substrate 101.

The microsphere 110 may be disposed on the upper surface of the stage. For example, the microsphere 110 may be disposed between the upper surface of the stage and the objective lens 120. The microsphere 110 may be spaced apart from each of the substrate 101 disposed on the stage and the objective lens 120. In some example embodiments, the microsphere 110 may be in the form of a sphere. However, it should be understood that the shape of the microsphere of various example embodiments is not limited thereto. The microsphere 110 may include a dielectric material with a refractive index of 1 or more. The microsphere 110 may include, for example, soda-lime glass. In some example embodiments, first light and second light, passing through the microsphere 110, may be focused on a focal point to be formed on the substrate 101. The focal point may be formed on a surface of the semiconductor pattern formed on the substrate 101. In some example embodiments, the microsphere 110 may have a diameter ranging from 1 μm to 100 μm in a first horizontal direction that is parallel to the upper surface of the stage. For example, the diameter of the microsphere 110 may be formed to be about 1/300ths or less than a diameter of the objective lens 120. The microsphere 110, having a diameter much smaller than the diameter of the objective lens 120, may be used to effectively focus at least one broadband light provided from the objective lens 120 onto the focal point formed on the substrate 101.

Light may pass through the microsphere 110 and may then be reflected to the focal point. The light, reflected to the focal point, may be defined as reflective light. The reflective light may sequentially pass through the objective lens 120 and a beam splitter 151 and be provided to the spectrometer 200. The spectrometer 200 may test the semiconductor pattern formed on the substrate 101 by detecting the reflective light.

The objective lens 120 may be disposed on the upper surface of the stage. The objective lens 120 may be disposed between the stage and the beam splitter 141 on a path through which light passes. Light, provided from the beam splitter 141, may pass through the objective lens 120 and be focused on the microsphere 110.

The objective lens position controller 130 may be connected to the objective lens 120. The objective lens position controller 130 may move the objective lens 120 in a vertical direction (e.g., a Z-direction) that is perpendicular to the substrate 101. In some example embodiments, the objective lens position controller 130 may be controlled by the distance measurement apparatus 400. The objective lens position controller 130 may include a Lead Zirconate Titanate (PZT) actuator. In general, a PZT material may have a piezoelectric effect. The piezoelectric effect may refer to a property of causing deformation in size or shape of an object as internal atoms of a material move when an electric field is applied to the PZT material. The PZT actuator may deform or move depending on an electrical input signal. When the electric field is applied, the PZT material may deform and/or may move. Such deformation may be implemented in various forms depending on a structure and design of the actuator. The PZT actuator may provide high precision and/or a rapid response speed.

The first optical system 140 may include a beam splitter 141 and at least one lens 142, 143, or 144. The beam splitter 141 may be disposed on a path along which light passes. The beam splitter 141 may reflect a portion of light that is provided from the light source 300, and may provide the light to the objective lens 120. In addition, the beam splitter 141 may transmit a remaining portion of the light, provided from the light source 300.

At least one lens 142, 143, or 144 may be disposed between the light source 300 and the beam splitter 141 on a path through which light passes. In some example embodiments, at least one polarizer may be disposed between the lenses 142, 143, or 144 and the beam splitter 141 on a path through which light passes. For example, light provided from the light source 300 may sequentially pass through the lens 142 and the polarizer and be provided to the beam splitter 141. In some example embodiments, at least one lens 142, 143, or 144 may be or may include a convex lens. For example, the lens 142 may change an angular distribution of the light provided from the light source 300 and provide the light to the polarizer. The polarizer may polarize light provided from the first lens 142 in one direction and provide the light to the beam splitter 141. In some example embodiments, the first optical system 140 may further include an aperture between the lenses 142, 143, and 144.

The second optical system 150 may include a beam splitter 151 and a lens 152. The beam splitter 151 and the lens 152 may be disposed on a path through which reflective light passes. The lens 152 may be disposed between the beam splitter 141 and the beam splitter 151 on the path through which the reflective light passes. In some example embodiments, the lens 152 may be or may include a convex lens. Reflective light reflected from a focal point may sequentially pass through the lens 152 and the beam splitter 151 and be provided to the spectrometer 200.

The camera 160 may be implemented to detect reflective light of first light and second light, passing through the beam splitter 151. The camera 160, a two-dimensional (2D) array detector, may be, include, or be included in, for example, a charge-coupled device (CCD) camera. It should be understood that the camera 160 is not limited to the CCD camera. The camera 160 may be on an image plane, serving as a general microscope imaging, and may be used to identify a measurement position within an object plane and an optimal focal position in an optical axis direction.

The spectrometer 200 may be implemented to obtain a spectrum of light reflected from the beam splitter 151 of the second optical system 150.

The light source 300 may be implemented to output at least one broadband light. In an example embodiment, the light source 300 may be implemented to extract light having a desired wavelength from light having a plurality of wavelengths. In some example embodiments, the light source 300 may provide first light or second light from the light having a plurality of wavelengths to the substrate 101 disposed on the stage.

The distance measurement apparatus 400 may be implemented to control an overall operation of the semiconductor measurement apparatus 10. For example, the distance measurement apparatus 400 may be implemented such that a broadband light source is irradiated to a specimen through an illumination optical system, a reflection spectrum is measured by the spectrometer 200, and a position of a microsphere-objective lens is controlled simultaneously with measurement of a spectrum. The distance measurement apparatus 400 may measure a spectral change due to a minimal change in position of the objective lens 120, and may calculate a distance between the specimen and a microsphere by analyzing such a spectral change.

The semiconductor measurement apparatus 10 according to various example embodiments may use interference generated in a microsphere optical system itself to determine a focal position based on a spectrum without an additional interferometer configuration, thereby enabling precise distance measurement.

FIGS. 6B, 6C, and 6D are example diagrams illustrating a method of measuring, by a semiconductor measurement apparatus 10, a distance according to various example embodiments. As illustrated in FIG. 6B, an objective lens position controller 130 may move a microsphere-objective lens. Here the microsphere-objective lens may be moved by a PZT actuator. In general, when a voltage is applied to the PZT actuator, internal molecules of the PZT actuator may be aligned, and accordingly a ceramic plate may be slightly lengthened or shortened. As illustrated in FIG. 6C, a spectral change according to the movement of the microsphere-objective lens may be measured. As illustrated in FIG. 6D, a distance between a microsphere and a specimen may be calculated based on a measured interference pattern.

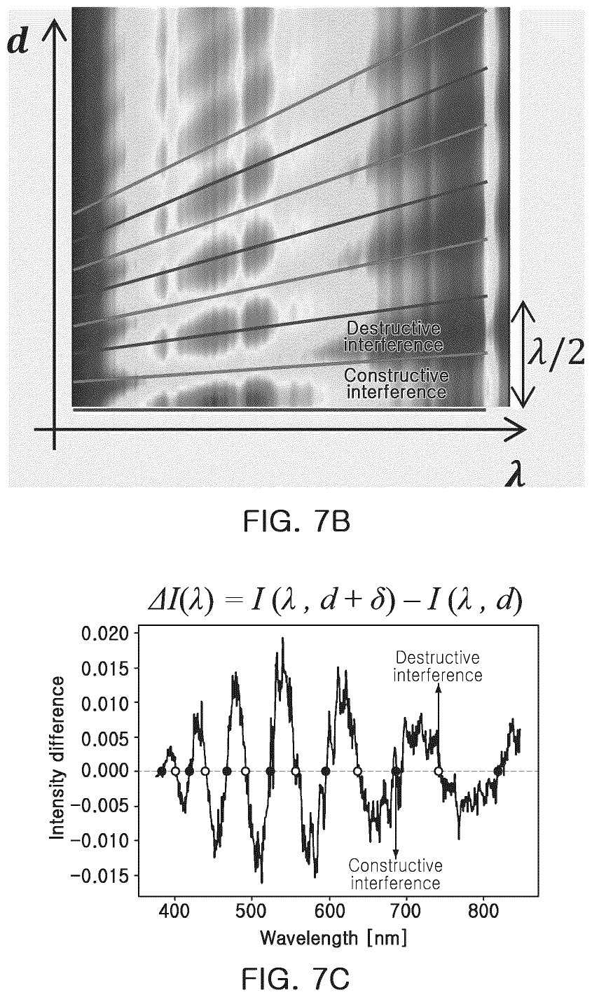

FIGS. 7A, 7B, and 7C are example diagrams illustrating an operating principle of a semiconductor measurement apparatus 10 according to various example embodiments. As illustrated in FIG. 7A, the semiconductor measurement apparatus 10 may use interference due to multiple reflection occurring between a microsphere and a specimen. Here, I_{O} may be or may refer to or be based on an intensity of incident light, I_{R} may be or may refer to or be based on an intensity of reflected light, and d may be a microsphere-specimen distance. As illustrated in FIG. 7B, constructive interference (mλ=2d) and destructive interference ((m+½)λ=2d) may appear alternately depending on a distance (d) between the microsphere and the specimen. In general, an interference pattern may depend on a wavelength (λ) and distance (d). As illustrated in FIG. 7C, when a change in the interference pattern according to a wavelength is measured, the distance (d) between the microsphere and the specimen corresponding to the measured change in the interference pattern may be calculated using the following equation.

$$Δ I ( λ ) = I ( λ , d + δ ) - I ( λ , d ) = 0 \qquad [ Equation 1 ]$$

Here, δ may be or may correspond to a slight change in distance between a microsphere and the specimen. As illustrated in FIG. 7D, when the distance between the microsphere and the specimen slightly changes, the interference pattern according to the wavelength may be measured using a change in spectrum.

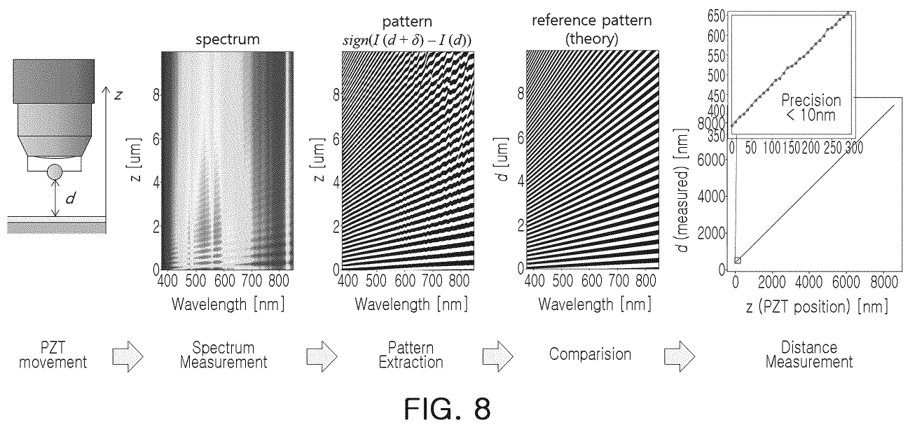

FIG. 8 is an example diagram illustrating a real-time distance measurement process of a semiconductor measurement apparatus 10 according to various example embodiments. The semiconductor measurement apparatus 10 may perform real-time distance measurement when a microsphere 110 approaches a specimen surface. Referring to FIG. 8, real-time distance measurement may be performed in the following order. The microsphere 110 may move at an interval of 10 nm in a direction of a specimen by moving a scanner (including a microsphere-objective lens). The distance measurement apparatus 400 may measure a spectrum while moving the microsphere 110. The distance measurement apparatus 400 may extract an interference pattern at every measurement interval. The distance measurement apparatus 400 may calculate a distance to the specimen by performing comparison with a theoretical formula. The semiconductor measurement apparatus 10 according to various example embodiments may further improve precision depending on performance of the scanner and a spectrometer. In addition, the semiconductor measurement apparatus 10 according to various example embodiments may move to a target position after measuring a distance once, rather than measuring a distance in all positions, thereby minimizing approaching time.

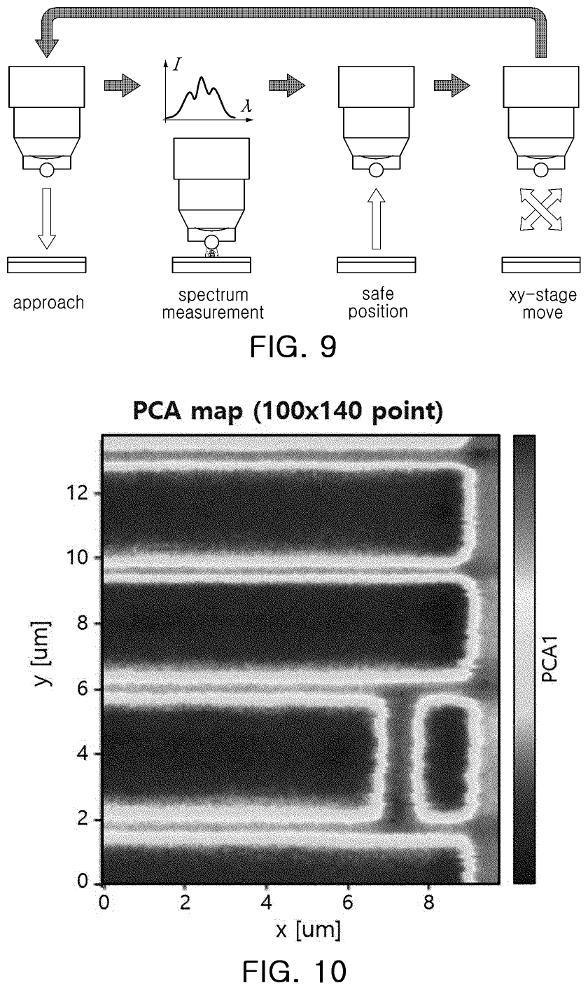

FIG. 9 is an example diagram illustrating a 2D region scanning of a semiconductor measurement apparatus 10 according to various example embodiments. Referring to FIG. 9, the semiconductor measurement apparatus 10 according to various example embodiments may rapidly and precisely move the microsphere 110 to a target position, and may use the microsphere 110 to obtain a spectrum in a 2D space.

2D scanning may require or may use distance measurement as follows: first, a change in specimen height during movement of an XY-stage, and second, a change in distance between a microsphere and a specimen due to drift of a stage and a scanner. The above two height changes may increase a risk of collision between the microsphere and the specimen, and may also reduce spectral repeatability. Accordingly, scanning a 2D space without precise position measurement may have a significant negative effect on safety and precision.

FIG. 10 is an example diagram illustrating a 2D spectrum map of a semiconductor measurement apparatus 10 according to various example embodiments. Referring to FIG. 10, the semiconductor measurement apparatus 10 may measure a distance between a microsphere 110 and a specimen, and may maintain a distance such as a dynamically determined (or, alternatively, a predetermined) distance between the microsphere 110 and the specimen when measuring a spectrum, thereby reducing a risk of collision and/or improving precision of spectrum measurement. Here, distance measurement may be performed in a cell region of the specimen. In addition, even when drift of several μm of a stage occurs while measuring the spectrum, measurement may be safely completed through position measurement. Once stability of the stage is ensured, structure measurement may be performed by measuring a height of the specimen.

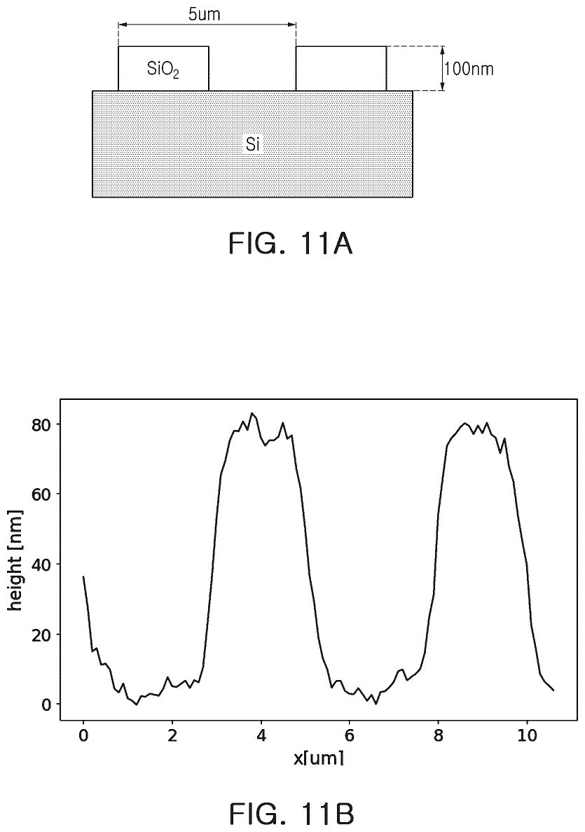

FIG. 11A is an example diagram illustrating a height standard specimen according to various example embodiments, and FIG. 11B is an example diagram illustrating a standard specimen measurement result according to various example embodiments. A distance measurement method of a semiconductor measurement apparatus according to various example embodiments may also measure a surface shape of a specimen. In order to verify a corresponding function, a height according to a position of the height standard specimen may be measured. As a result of the measurement, a step of 100 nm may be measured. In this case, it may be determined that deviations included in the measurement and poor repeatability are caused by performance of a stage. When equipment is improved for height measurement, a principle according to various example embodiments may improve performance up to a precision of 1 nm in a height direction and 100 nm in an X-direction.

The semiconductor measurement apparatus 10 and a method of manufacturing a semiconductor device using the same according to various example embodiments enables a precision distance measurement method applicable to a super-high-resolution optical system including a microsphere 110. The semiconductor measurement apparatus 10 according to various example embodiments may measure a distance between a microsphere and a specimen with an accuracy of several nm in a region of several tens of μm. The semiconductor measurement apparatus 10 according to various example embodiments may not only improve one or more of safety, working speed, and precision of a microsphere optical system by enabling real-time precise distance measurement, but may alternatively or additionally be applied to measure a height and/or thickness of the specimen.

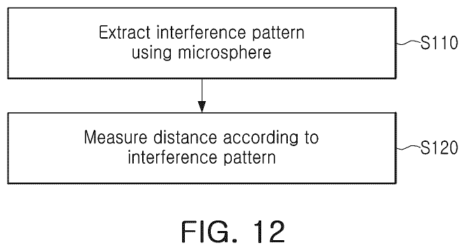

FIG. 12 is an example flowchart illustrating an operation of a semiconductor measurement apparatus according to various example embodiments. Referring to FIGS. 1 to 12, an operation of a measurement apparatus may be performed as follows. An interference pattern may be extracted using a microsphere (S110). In some example embodiments, a first spectrum may be measured, a microsphere-objective may be moved in a direction, perpendicular to a specimen, a second spectrum may be measured, a spectral difference between the first spectrum and the second spectrum may be calculated, and an interference pattern corresponding to the spectral difference may be calculated. A distance may be measured based on the extracted interference pattern (S120). In some example embodiments, the calculated interference pattern and a reference pattern may be compared to each other, and a distance between the microsphere and the specimen corresponding to a comparison result may be calculated.

In some example embodiments, the measurement location of the micro-objective lens may be set. In some example embodiments, the microsphere-objective lens may be moved by less than 10 nm by a PZT (Lead Zirconate Titanate) actuator. In some example embodiments, a reference pattern may be set. In some example embodiments, the microsphere may be implemented in spherical, hemispherical, or rod shapes. In some example embodiments, the microsphere may be fixed below a predetermined distance of the objective lens. In some example embodiments, a spot scanning operation may be performed while maintaining a constant height of the microsphere-objective lens. In some example embodiments, during the spot scanning operation, the position of the scanner and the distance between the microsphere and the sample may be measured, and the error corresponding to the position of the scanner in the microsphere-sample distance may be corrected or at least partially corrected.

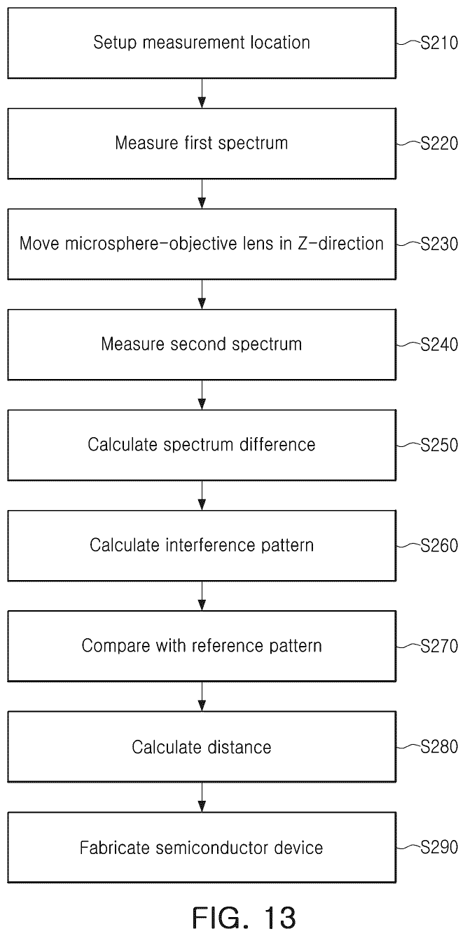

FIG. 13 is an example flowchart illustrating an operation of manufacturing a semiconductor device using a semiconductor measurement apparatus according to various example embodiments. Referring to FIGS. 1 to 11 and 13, an operation of the semiconductor measurement apparatus may be performed as follows. A measurement position may be set (S210). A first spectrum may be measured in the measurement position (S220). The microsphere-objective lens may be moved in a vertical direction (Z-direction) (S230). For example, a movement step may be 10 nm or less. A second spectrum may be measured in the measurement position (S240). A difference between the first spectrum and the second spectrum may be calculated (S250). An interference pattern, corresponding to such a spectral difference, may be calculated (S260). A reference pattern and the calculated interference pattern may be compared to each other (S270). A distance may be calculated based on a comparison result (S280). A semiconductor device may be fabricated, e.g., based on the distance (S290).

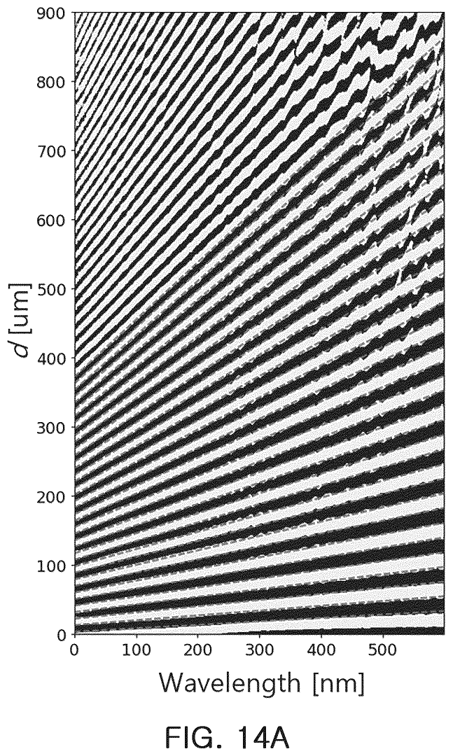

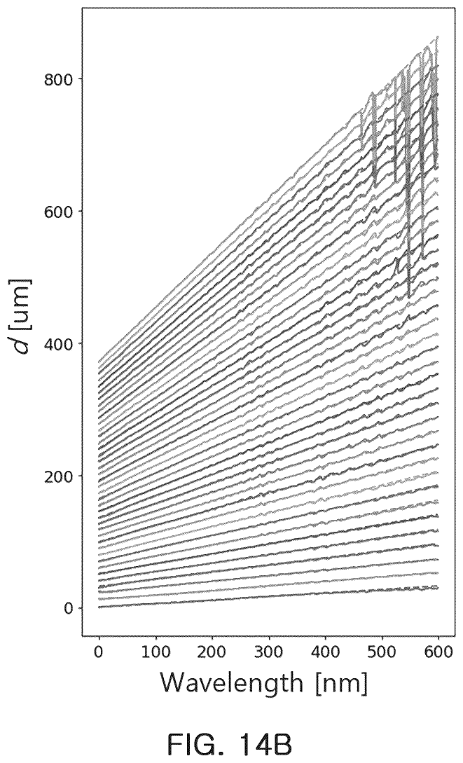

FIGS. 14A, 14B, and 14C are example diagrams illustrating obtaining of a reference pattern according to various example embodiments. As illustrated in FIG. 14A, an interference pattern may be measured in an actual optical system. As illustrated in FIG. 14B, the measured interference pattern may be fitted with mλₘ=2dr. As illustrated in FIG. 14C, a reference pattern, matching a theoretical equation, may be obtained from the fitted interference pattern. The semiconductor measurement apparatus 10 according to various example embodiments may obtain a reference pattern, based on data measured to reflect properties of an actual optical system, spectrometer, stage, or the like.

Various example embodiments may be used to measure a shape and/or a step of a specimen.

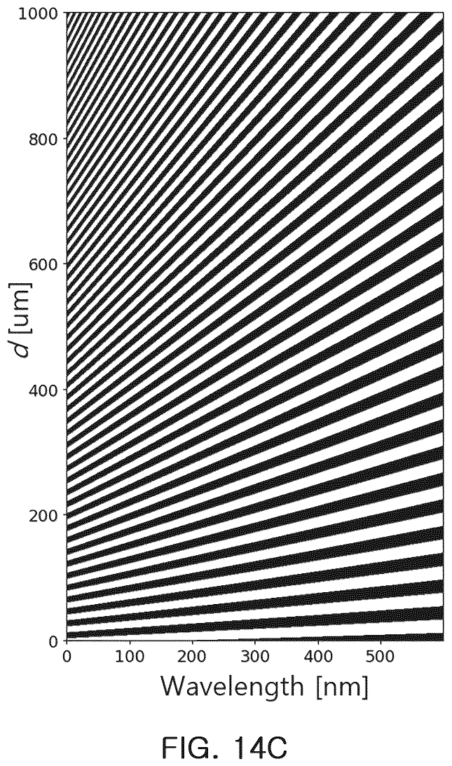

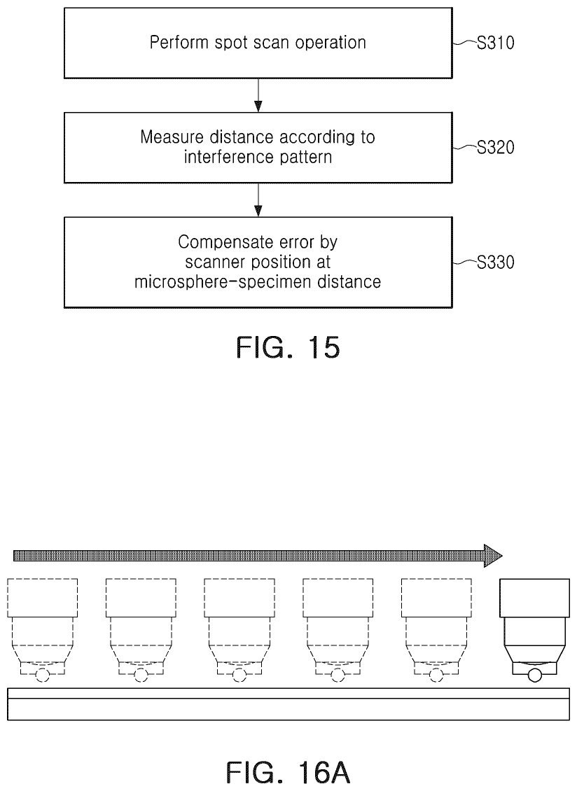

FIG. 15 is an example flowchart illustrating an operation of a semiconductor measurement apparatus according to various example embodiments. Referring to FIGS. 1 to 15, a semiconductor measurement apparatus 10 may measure a shape/step of a specimen as follows. A spot scanning operation may be performed using a scanner having a microsphere-objective lens (S310). In some example embodiments, the scanner may be moved using a PZT actuator. In some example embodiments, the spot scanning operation may have a resolution corresponding to a spot of 100 nm or less. A microsphere-specimen distance may be calculated based on an interference pattern corresponding to the spot scanning operation (S320). In some example embodiments, a spectrum of light reflected from a surface of the specimen may be measured, an interference pattern may be extracted from the measured spectrum, a reference pattern may be compared to the extracted interference pattern, and the microsphere-specimen distance may be calculated based on a comparison result. An error in the microsphere-specimen distance, corresponding to a position of the scanner, may be compensated for (S330). In some example embodiments, the scanner may perform real-time distance measurement to prevent collision with the specimen due to a stage vibration or a change in specimen height.

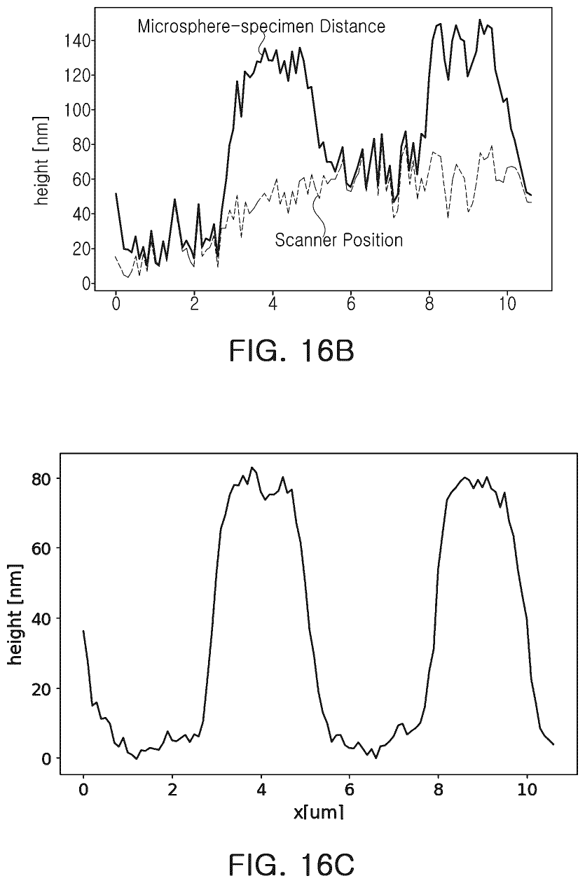

FIGS. 16A, 16B, and 16C are example diagrams illustrating measuring, by a semiconductor measurement apparatus, a surface shape of a specimen according to various example embodiments. As illustrated in FIG. 16A, a spot scanning operation may be performed while maintaining a predetermined height of a microsphere-objective lens. As illustrated in FIG. 16B, a position of a scanner and a microsphere-specimen distance may be measured in the spot scanning position. As illustrated in FIG. 16C, an error in the microsphere-specimen distance may be compensated for to correspond to the position of the scanner. In order to improve a measurement result, it may be necessary or desirable to improve scanner performance.

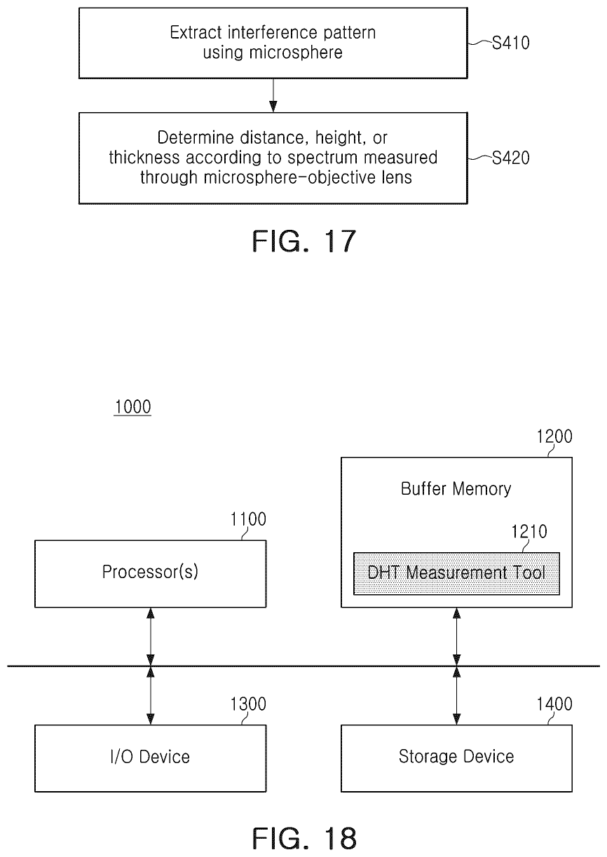

FIG. 17 is a flowchart illustrating an operation of a measurement apparatus according to various example embodiments. Referring to FIGS. 1 to 17, the measurement apparatus may operate as follows. An interference pattern may be extracted using a microsphere (S410). One or more of a distance, height, or thickness may be determined based on a spectrum measured through a microsphere-objective lens (S420). In some example embodiments, a focal position may be determined based on a spectrum measured on a surface of the specimen. In some example embodiments, an interference pattern and a reference pattern may be compared to each other. Here, the reference pattern may be obtained based on data measured to reflect properties of an optical system, spectrometer, or stage. In some example embodiments, a microsphere-specimen distance may be compensated for or at least partly compensated for to correspond to a position of a scanner.

In general, a microsphere may simply overcome an optical diffraction limit by improving a microscope optical system according to the related art. A semiconductor measurement apparatus and working distance measurement of a microsphere optical system using the same according to various example embodiments may enable non-destructive testing and measurement of a semiconductor using a microsphere. Various example embodiments may be applicable to all application devices for identifying whether one or more of a distance, height, thickness, or the like is determined based on a spectrum measured through a microsphere-objective lens.

FIG. 18 is a block diagram illustrating a computing device 1000 performing a semiconductor measurement operation according to various example embodiments. Referring to FIG. 18, the computing device 1000 may include at least 1400 processor 1100, a memory device 1200, an input/output device 1300, and a storage device 1400. Through a system bus, the processor 1100, the memory device 1200, the input/output device 1300, and the storage device 1400 may be electrically connected to each other and may exchange data with each other. A configuration of the system bus 1001 is not limited to the above-described configuration, and may further include mediation measures for efficient management.

The at least one processor 1100 may be implemented to control an overall operation of the computing device 1000. The processor 1100 may be implemented to execute at least one instruction. For example, the processor 1100 may be implemented to execute software (application programs, operating systems, and device drivers) to be executed in the computing device 1000. The processor 1100 may execute an operating system loaded into the memory device 1200. The processor 1100 may execute various application programs to be driven based on an operating system. For example, the processor 1100 may drive a rendering tool 1220 read from the memory device 1200. In some example embodiments, the processor 1100 may be or include, or be included in, one or more of a central processing unit (CPU), a microprocessor, an application processor (AP), or any processing device similar thereto. In some example embodiments, the processor 1100 may be implemented to execute a measurement tool 1210.

The memory device 1200 may be implemented to store at least one instruction. For example, the memory device 1200 may be loaded with the operating system or application programs. During booting of the computing device 1000, an OS image stored in the storage device 1400 may be loaded into the memory device 1200, based on a booting sequence. Input and output operations of the computing device 1000 may be supported by the operating system. Similarly, the application programs may be loaded into the memory device 1200 to provide a service selected by a user or a basic service.

In particular, the measurement tool 1210, measuring a distance/height/thickness, may be loaded into the memory device 1200 from the storage device 1400. The measurement tool 1210 may measure the distance/height/thickness of a specimen by controlling the semiconductor measurement apparatus and operation thereof described with reference to FIGS. 1 to 17. The measurement tool 1210 may extract an interference pattern corresponding to a change in spectrum of light reflected from the specimen using a microsphere, and may determine a microsphere-specimen distance, a height of the specimen, or a thickness of the specimen, based on the interference pattern. In an example embodiment, the measurement tool 1210 may calculate the microsphere-specimen distance by comparing the interference pattern to a reference pattern. In an example embodiment, the measurement tool 1210 may compensate for an error in the microsphere-specimen distance to correspond to a position of a scanner. In some example embodiments, the measurement tool 1210 may obtain a spectral change while changing the position of the scanner to perform a spot scanning operation.

In some example embodiments, the memory device 1200 may be or may include a volatile memory such as one or more of dynamic random access memory (DRAM), static random access memory (SRAM), or the like, and/or a nonvolatile memory such as one or more of flash memory, phase change random access memory (PRAM), resistance random access memory (RRAM), nano floating gate memory (NFGM), polymer random access memory (PoRAM), magnetic random access memory (MRAM), ferroelectric random access memory (FRAM), or the like.

The input/output device 1300 may be implemented to control an input and an output of a user from a user interface device. For example, the input/output device 1300 may include an input measure such as a keyboard, a keypad, a mouse, and a touch screen to receive information from a designer. The designer may use the input/output device 1300 to receive information about semiconductor region or data paths, requiring adjusted operating properties. In addition, the input/output device 1300 may include an output measure such as a printer, a display, or the like to display a process and a result of the rendering tool 1220.

The storage device 1400 may be provided as a storage medium of the computing device 1000. The storage device 1400 may store application programs, an OS image, and a measurement tool. The storage device 1400 may be provided in the form of, or may include or be included in, for example, one or more of a mass storage device such as a memory card (one or more of MMC, eMMC, SD, Micro SD, or the like), a hard disk drive (HDD), a solid-state drive (SSD), a universal flash storage (UFS), or the like.

The device described above may be implemented as a hardware component, a software component, and/or a combination of the hardware component and the software component. For example, a device and a component according to various example embodiments may be implemented using one or more general purpose or special purpose computers, such as a processor, controller, arithmetic logic unit (ALU), digital signal processor, microcomputer, field programmable gate array (FPGA), programmable logic unit (PLU), microprocessor, or any other device capable of executing and responding to instructions. A processing device may include an operating system (OS) and one or more software applications executed on the operating system. In addition, the processing device may also access, store, manipulate, process, and generate data in response to execution of software. For ease of understanding, in some case, it is described that the processing device is used a single processing element, but those of ordinary skill in the art could recognize that the processing device may include a plurality of processing elements or multiple types of processing elements. For example, the processing device may include a plurality of processors, or one processor and one controller. In addition, other processing configurations are also possible, such as parallel processors.

The software may include a computer program, a code, an instruction, or one or more combinations thereof, and may configure the processing device to operate as desired, or may independently or collectively instruct the processing device. The software and/or data may be embodied in any type of machine, component, physical device, virtual equipment, computer storage medium, or device so as to be interpreted by the processing device, or to provide instructions or data to the processing device. The software may also be distributed on a computer system via a network, and may be stored or executed in a distributed manner. The software and data may be stored on one or more computer-readable recording media.

A semiconductor measurement apparatus according to various example embodiments may include a broadband light source, a spectrometer, an objective lens including a microsphere, and a position control device of an optical system. A distance measurement method of a semiconductor measurement apparatus according to various example embodiments may include obtaining a spectrum in one or more positions having a small displacement difference, obtaining an interference pattern through spectrum change analysis, and measuring a distance between the microsphere and a specimen using the interference pattern. In some example embodiments, the microsphere is not limited to a sphere, and may be implemented in a form of generating a light-gathering effect. For example, microsphere may be used in the form of a hemisphere and a rod. In some example embodiments, the optical system position control device may be any control device capable of transferring the objective lens or the entire optical system in a direction, perpendicular to the ground. In some example embodiments, the objective lens, including the microsphere fixed thereto, may be implemented in a form in which the microsphere is positioned on a lower portion of the objective lens by a predetermined distance. Here, any method, not interfering with an optical path, such as fixation using an optical adhesive or an instrument, may be used as a method of fixing the microsphere.

According to various example embodiments, safety may be improved by preventing collision between a microsphere and a specimen through precise distance measurement. Alternatively or additionally according to various example embodiments, safety may be ensured based on real-time distance measurement, and working speed may be improved by increasing control speed of the microsphere. Alternatively or additionally according to various example embodiments t, a working distance may be maintained through precise distance measurement, and spectrum measurement repeatability may be improved. Alternatively or additionally according to various example embodiments, an operation may be performed in an imaging position, and a height of a microstructure may be measured.

Alternatively or additionally according to various example embodiments there is a distance measurement technology that may be used when using a microsphere for super-resolution spectroscopic measurement. Spectroscopic measurement according to the related art may not provide a resolution corresponding to a critical dimension (CD) value of an increasingly minimized semiconductor process, and accordingly demand for modern technologies has been increasing, and a microsphere optical system, achieving super-resolution, is one of the modern technologies. The microsphere optical system has many differences from an optical system according to the related art, and modern technologies are required accordingly. The technology is applicable to most technologies (imaging, spectroscopy, and the like) using a microsphere, and is also applicable to specimen surface shape measurement and thickness measurement.

In a semiconductor measurement apparatus and a method of manufacturing a semiconductor device using the same according to various example embodiments, control may be performed to ensure specimen safety, repeatability, and precision of a spectrometer using a microsphere. In the semiconductor measurement apparatus and manufacturing method according to the various example embodiments, measurement repeatability may be improved through a position control technology having a precision of 10 nm or less. Alternatively or additionally, the semiconductor measurement apparatus and manufacturing method according to the present inventive concept, safety of a specimen and an optical system may be ensured from a collision issue even at a very short working distance. In the semiconductor measurement apparatus and manufacturing method according various example embodiments, throughput may be improved through rapid and accurate microsphere control.

Semiconductor measurement equipment according to various example embodiments may achieve super-resolution without an issue such as specimen destruction or contamination, using a microsphere. In particular, when applied to semiconductor spectroscopic measurement, testing and measurement may be performed, based on high resolution, on a non-repeating structure and a cell outer portion. According to various example embodiments, the microsphere may be one or more of safely, rapidly, and accurately controlled for use in spectroscopic measurement due to various properties such as a short working distance of the microsphere, spectral sensitivity to the working distance, and the like. A distance measurement technology according to various example embodiments may enable the microsphere to be safely, rapidly, and accurately controlled, thereby promoting commercialization of a technology using the microsphere. Alternatively or additionally according to various example embodiments, a measured distance may be used to analyze a specimen surface shape or to measure a thickness. A result of the measurement may have super-resolution, and thus may be suitable for testing and measurement of a semiconductor having a microstructure, as compared to a technology according to the related art.

In a semiconductor measurement apparatus and a method of manufacturing a semiconductor device using the same according to various example embodiments, precise distance measurement may be performed using an interference effect generated in a microsphere optical system itself.

Alternatively or additionally collision with a specimen may be prevented by measuring distance in real time.

Alternatively or additionally, rapid and precise control may be performed during distance measurement.

Alternatively or additionally, distance measurement may be performed in an imaging position and height measurement of a micro-region may be performed.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While various example embodiments have been shown and described above, it will be apparent to those of ordinary skill in the art that modifications and variations could be made without departing from the scope of the present inventive concept as defined by the appended claims. Additionally, example embodiments are not necessarily mutually exclusive with one another. For example, some example embodiments may include one or more features described with reference to one or more figures, and may also include one or more other features described with reference to one or more other figures.

1. A method of manufacturing a semiconductor device using a semiconductor measurement apparatus comprises:
extracting an interference pattern using a microsphere; and
measuring a distance between a specimen and the microsphere, based on the interference pattern.

2. The method of claim 1, further comprising:
setting a measurement position of a microsphere-objective lens.

3. The method of claim 1, wherein the extracting the interference pattern includes:
measuring a first spectrum;
moving a microsphere-objective lens structure including the microsphere and an objective lens in a direction that is perpendicular to a surface of the specimen;
measuring a second spectrum;
calculating a spectral difference between the first spectrum and the second spectrum; and
calculating the interference pattern corresponding to the spectral difference.

4. The method of claim 3, wherein the moving the microsphere-objective lens includes moving the microsphere-objective lens with a lead zirconate titanate (PZT) actuator by 10 nm or less.

5. The method of claim 3, wherein the measuring the distance includes:
comparing the calculated interference pattern and a reference pattern to each other; and
calculating the distance between the microsphere and the specimen corresponding to a comparison result.

6. The method of claim 5, further comprising:
setting the reference pattern.

7. The method of claim 1, wherein the microsphere has a form of at least one of a sphere, a hemisphere, or a rod.

8. The method of claim 1, wherein the microsphere is fixed to a lower portion of an objective lens by a fixed distance.

9. The method of claim 1, further comprising:
performing a spot scanning operation while maintaining a height of a microsphere-objective lens that includes the microsphere and an objective lens.

10. The method of claim 9, further comprising:
measuring a position of a scanner and a microsphere-specimen distance in the spot scanning operation; and
compensating for an error in the microsphere-specimen distance corresponding to the position of the scanner.

11. A method of manufacturing a semiconductor device using a semiconductor measurement apparatus, the method comprising:
performing a spot scanning operation on a specimen while moving a scanner having a microsphere-objective lens;
measuring a microsphere-to-specimen distance, based on an interference pattern generated in the spot scanning operation; and
compensating for an error of the scanner in the microsphere-to-specimen distance.

12. The method of claim 11, wherein the performing the spot scanning operation includes moving the scanner using a lead zirconate titanate (PZT) actuator.

13. The method of claim 11, wherein the measuring the microsphere-to-specimen distance includes:
measuring a spectrum of light reflected from a surface of the specimen;
extracting an interference pattern from the measured spectrum;
comparing a reference pattern and the extracted interference pattern to each other; and
calculating the microsphere-to-specimen distance, based on a comparison result.

14. The method of claim 11, wherein real-time distance measurement reduces collision with the specimen due to at least one of a stage vibration or a change in specimen height.

15. The method of claim 11, wherein the spot scanning operation has a resolution corresponding to a spot of 100 nm or less.

16. A method of manufacturing a semiconductor device using a semiconductor measurement apparatus, the method comprising:
extracting an interference pattern for light reflected from a specimen by using a microsphere; and
determining at least one of a distance to the specimen, a height of the specimen, or a thickness of the specimen, based on a spectrum through the microsphere-objective lens corresponding to the interference pattern.

17. The method of claim 16, further comprising:
determining a focal position, based on the spectrum measured on a surface of the specimen.

18. The method of claim 16, further comprising:
comparing the interference pattern and a reference pattern to each other.

19. The method of claim 18, further comprising:
obtaining the reference pattern, based on data measured to reflect properties of at least one of an optical system, a spectrometer, or a stage.

20. The method of claim 16, further comprising:
compensating for an error in an microsphere-to-specimen distance to correspond to a position of a scanner.

21-30. (canceled)
